(19) United States
(12) Patent Application Publication
(10) Pub. No.: US 2025/0379551 A1
(43) Pub. Date: Dec. 11, 2025

(54) AMPLIFYING CIRCUIT

(71) Applicant: SUMITOMO ELECTRIC INDUSTRIES, LTD., Osaka (JP)

(72) Inventor: Hirotaka ASAMI, Osaka-shi (JP)

(73) Assignee: SUMITOMO ELECTRIC INDUSTRIES, LTD., Osaka (JP)

(21) Appl. No.: 19/230,441

(22) Filed: Jun. 6, 2025

(30) Foreign Application Priority Data
Jun. 11, 2024 (JP) 2024-094571

(51) Int. Cl. H03F 3/60; H03F 1/56; H03F 3/24

(52) U.S. Cl. CPC H03F 3/604; H03F 1/565; H03F 3/245

(57) ABSTRACT

An amplifying circuit includes a first divider that divides an input signal into a first signal and a second signal, a first amplifier that amplifies the first signal, a second amplifier that amplifies the second signal, a combiner that combines the first signal and the second signal to output the combined signal as an output signal, and at least one composite right/left-handed transmission line connected to at least one of a first line connecting the first divider to the first amplifier or a second line connecting the first divider to the second amplifier, the at least one composite right/left-handed transmission line adjusting a phase of at least one of the first signal flowing through the first line and the second signal flowing through the second line.

### CROSS REFERENCE TO RELATED APPLICATIONS

This application claims priority based on Japanese Patent Application No. 2024-094571 filed on Jun. 11, 2024, and the entire contents of the Japanese patent application are incorporated herein by reference.

### TECHNICAL FIELD

The present disclosure relates to an amplifying circuit.

### BACKGROUND

As an amplifying circuit for amplifying a high frequency signal such as a microwave, a load modulated balanced amplifier (LMBA) is known (see, non-patent literature: “Broadband RF-Input Continuous-Mode Load-Modulated Balanced Power Amplifier With Input Phase Adjustment” Jingzhou Pang et. al. IEEE TRANSACTIONS ON MICROWAVE THEORY AND TECHNIQUES Vol. 68, No. 10 Oct. 2020, pp. 4466 to 4478).

### SUMMARY

An amplifying circuit according to an embodiment of the present disclosure includes a first divider that divides an input signal into a first signal and a second signal, a first amplifier that amplifies the first signal, a second amplifier that amplifies the second signal, a combiner that combines the first signal and the second signal to output the combined signal as an output signal, and at least one composite right/left-handed transmission line connected to at least one of a first line connecting the first divider to the first amplifier or a second line connecting the first divider to the second amplifier, the at least one composite right/left-handed transmission line adjusting a phase of at least one of the first signal flowing through the first line and the second signal flowing through the second line.

### BRIEF DESCRIPTION OF THE DRAWINGS

FIG. 1A is a circuit diagram illustrating an amplifying circuit according to a first embodiment.

FIG. 1B is a diagram illustrating a FET.

FIG. 2A is a diagram illustrating phase dispersion.

FIG. 2B is a diagram illustrating a phase of a signal.

FIG. 2C is a diagram illustrating a phase of a signal.

FIG. 3 is a circuit diagram illustrating an amplifying circuit according to a second embodiment.

FIG. 4 is a circuit diagram illustrating an amplifying circuit according to a third embodiment.

FIG. 5 is a circuit diagram illustrating an amplifying circuit according to a comparative example.

FIG. 6A is a diagram illustrating phases.

FIG. 6B is a diagram illustrating drain efficiency.

FIG. 6C is a plan view illustrating a transmission line.

FIG. 6D is a plan view illustrating one composite right/left-handed transmission line (CRLH line).

FIG. 7 is a circuit diagram illustrating an amplifying circuit according to a fourth embodiment.

FIG. 8 is a circuit diagram illustrating an amplifying circuit according to a fifth embodiment.

### DETAILED DESCRIPTION

The amplifying circuit combines a plurality of signals and outputs the combined signal. By adjusting the phases of the signals at the time of combining, characteristics such as efficiency are improved. When the phases of the signals deviate from the optimum values, the characteristics deteriorate. A phase adjustment line is provided to adjust the phases.

The amplifying circuit is required to widen an operating band. Thus, the phase adjustment line is also required to optimize the phase in the wide operating band. When a transmission line is used as the phase adjustment line, the line length increases. As a result, the amplifying circuit is increased in size. When the transmission line is reduced in size, it is difficult to adjust the phase in the wide operating band. An object of the present disclosure is to provide an amplifying circuit that can be reduced in size and can widen an operating band.

### Description of Embodiments of Present Disclosure

First, the contents of embodiments of the present disclosure will be listed and explained.
(1) An amplifying circuit according to an embodiment of the present disclosure includes a first divider that divides an input signal into a first signal and a second signal, a first amplifier that amplifies the first signal, a second amplifier that amplifies the second signal, a combiner that combines the first signal and the second signal to output the combined signal as an output signal, and at least one composite right/left-handed transmission line connected to at least one of a first line connecting the first divider to the first amplifier or a second line connecting the first divider to the second amplifier, the at least one composite right/left-handed transmission line adjusting a phase of at least one of the first signal flowing through the first line or the second signal flowing through the second line. The composite right/left-handed transmission line allows the phase of the signal to be adjusted in the wide operating band. Further, the line length does not need to be increased. Thus, the amplifying circuit can be reduced in size and can widen the operating band.
(2) In the above (1), the combiner may be a load modulation circuit that modulates a load of the second amplifier, and the amplifying circuit may be a load modulated balanced amplifier. The load modulated balanced amplifier can be reduced in size and can widen the operating band.
(3) In the above (2), the amplifying circuit may further include a second divider provided in the second line. The second divider may divide the second signal into a third signal and a fourth signal, the second amplifier may include a third amplifier and a fourth amplifier, the third amplifier may that amplify the third signal, the fourth amplifier may amplify the fourth signal, and the at least one composite right/left-handed transmission line may be connected to at least one of the first line and the second line between the first divider and the second divider. The load modulated balanced amplifier can be reduced in size and can widen the operating band.
(4) In the above (3), the combiner may have a first end, a second end, a third end, and a fourth end, the third signal amplified by the third amplifier may be input to the first end, the fourth signal amplified by the fourth amplifier may be input to the second end, the first signal amplified by the first amplifier may be input to the third end, and the output signal may be output from the fourth end. The composite right/left-handed transmission line brings the phases of the signals at the time of combining in the combiner close to optimum. The amplifying circuit can widen the operating band.
(5) In the above (3) or (4), the at least one composite right/left-handed transmission line may include a plurality of composite right/left-handed transmission lines, and the plurality of composite right/left-handed transmission lines may be connected to at least one of the first line and the second line between the first divider and the second divider. The amplifying circuit can be reduced in size and can widen the operating band.
(6) In the above (5), the at least one composite right/left-handed transmission lines may include three or more composite right/left-handed transmission lines. The amplifying circuit can be reduced in size and can widen the operating band.
(7) In any one of the above (1) to (6), the at least one composite right/left-handed transmission line may include a first inductor, a first capacitor, a second inductor, and a second capacitor, when the at least one composite right/left-handed transmission line is provided in the first line, the first inductor and the first capacitor may be connected in series to the first line, and the second inductor and the second capacitor may be shunt-connected between the first capacitor and the first amplifier, and when the at least one composite right/left-handed transmission line is provided in the second line, the first inductor and the first capacitor may be connected in series to the second line, and the second inductor and the second capacitor may be shunt-connected between the first capacitor and the second amplifier. Since the first capacitor has a function of DC blocking, the amplifying circuit can be reduced in size.
(8) In the above (7), the second inductor may be connected to a bias power supply, the bias power supply may supply a bias voltage to the first amplifier when the at least one composite right/left-handed transmission line is provided in the first line, and the bias power supply may supply a bias voltage to the second amplifier when the at least one composite right/left-handed transmission line is provided in the second line. Since another bias circuit does not need to be provided, the amplifying circuit can be reduced in size.
(9) In any one of the above (1) to (8), the at least one composite right/left-handed transmission line may include a first composite right/left-handed transmission line and a second composite right/left-handed transmission line, the first composite right/left-handed transmission line may be provided in the first line, and the second composite right/left-handed transmission line may be provided in the second line. The phases of the first signal and the second signal can be adjusted.

### Details of Embodiments of Present Disclosure

Specific examples of the amplifying circuit according to the embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

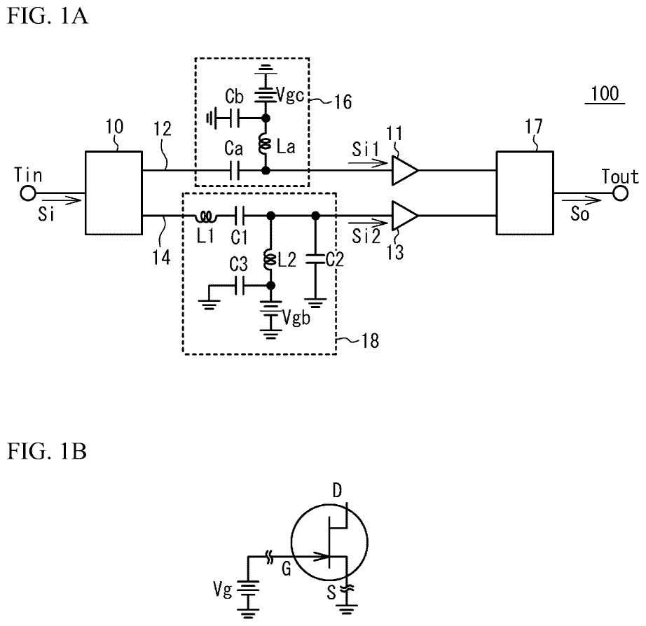

FIG. 1A is a circuit diagram illustrating an amplifying circuit 100 according to a first embodiment. Amplifying circuit 100 amplifies a signal Si input from an input terminal Tin and outputs an output signal So from an output terminal Tout. Signal So is a high frequency signal. The frequency of the high frequency signal is, for example, 0.5 GHz to 10 GHz.

A divider 10 (first divider) is connected to input terminal Tin. An amplifier 11 (first amplifier) is connected to one of output ends of divider 10. An amplifier 13 (second amplifier) is connected to the other of output ends of divider 10.

Amplifier 11 and amplifier 13 are, for example, field effect transistors (FETs). The FET is, for example, a gallium nitride high electron mobility transistor (GaN HEMT) or a laterally diffused metal oxide semiconductor (LDMOS). FIG. 1B is a diagram illustrating a FET. As illustrated in FIG. 1B, in each of amplifier 11 and amplifier 13, a source of the FET is grounded, and a bias voltage is applied to a gate. A high frequency signal is input to the gate, and a high frequency signal is output from a drain. Each of amplifier 11 and amplifier 13 may include a multistage FET.

Amplifier 11 is connected to one of input ends of a combiner 17. Amplifier 13 is connected to the other of input ends of combiner 17. An output end of combiner 17 is connected to output terminal Tout.

A line between divider 10 and amplifier 11 is referred to as a line 12 (first line). A line between divider 10 and amplifier 13 is referred to as a line 14 (second line).

A bias circuit 16 is provided in line 12. Bias circuit 16 includes a bias power supply Vgc, an inductor La, a capacitor Ca, and a capacitor Cb. Capacitor Ca is connected in series between divider 10 and amplifier 11. One end of inductor La is connected between capacitor Ca and amplifier 11. Bias power supply Vgc is connected to the other end of inductor La. One end of capacitor Cb is connected between inductor La and bias power supply Vgc. The other end of capacitor Cb is grounded. Bias power supply Vgc is a DC power supply. A bias voltage is supplied from bias circuit 16 to amplifier 11.

A composite right/left-handed transmission line (CRLH) 18 is provided in line 14. Composite right/left-handed transmission line 18 includes an inductor L1 (first inductor), an inductor L2 (second inductor), a capacitor C1 (first capacitor), and a capacitor C2 (second capacitor). As described later, the capacitors and the inductors in composite right/left-handed transmission line 18 are, for example, chip components.

Inductor L1 and capacitor C1 are connected in series in this order between divider 10 and amplifier 13. Inductor L2 and capacitor C2 are shunt-connected between capacitor C1 and amplifier 13. One end of capacitor C2 is connected between capacitor C1 and amplifier 13. The other end of capacitor C2 is grounded.

One end of inductor L2 is connected to a position closer to divider 10 than a position where capacitor C2 is connected, in the line between capacitor C1 and amplifier 13. A bias power supply Vgb is connected to the other end of inductor L2. Bias power supply Vgb is a DC power supply, and supplies a bias voltage to amplifier 13. One end of a capacitor C3 is connected between inductor L2 and bias power supply Vgb. The other end of capacitor C3 is grounded. Capacitor C3 grounds bias power supply Vgb in a high-frequency manner, and thus a high frequency signal is less likely to flow to bias power supply Vgb. Bias power supply Vgb of composite right/left-handed transmission line 18 supplies a bias voltage to amplifier 13.

The capacitances of capacitor C1 and capacitor C2 are denoted by C1 and C2, respectively. The inductances of inductor L1 and inductor L2 are denoted by L1 and L2, respectively. A characteristic impedance ZO of composite right/left-handed transmission line 18 is expressed by the following equation 1.

$$Z 0 = \sqrt{\frac{L 1}{C 2}} = \sqrt{\frac{L 2}{C 1}} \qquad [ Equation 1 ]$$

Composite right/left-handed transmission line 18 is designed so that an impedance of a port to which composite right/left-handed transmission line 18 is connected and characteristic impedance ZO of composite right/left-handed transmission line 18 match. In the design of composite right/left-handed transmission line 18, a phase of the signal is also considered as described later.

Signal Si is input from input terminal Tin. Divider 10 divides signal Si into a signal Si1 (first signal) and a signal Si2 (second signal). Signal Si1 propagates through line 12, amplified by amplifier 11, and is input to combiner 17. Signal Si2 propagates through line 14, passes through composite right/left-handed transmission line 18, is amplified by amplifier 13, and is input to combiner 17. Composite right/left-handed transmission line 18 adjusts a phase of signal Si2. Combiner 17 combines signal Si1 and signal Si2 and outputs the combined signal as signal So to output terminal Tout.

By bringing the phases of the signals at the time of combining in combiner 17 close to the optimum values, characteristics such as efficiency are improved. However, in a high-frequency circuit, a phase delay of a signal may be a problem. When the phase deviates from the optimum value, the characteristics such as efficiency deteriorate. The optimum phase at the time of combining differs depending on the frequency. In order to widen an operating band of amplifying circuit 100, the phases of the signals to be combined are optimized in a wide operating band.

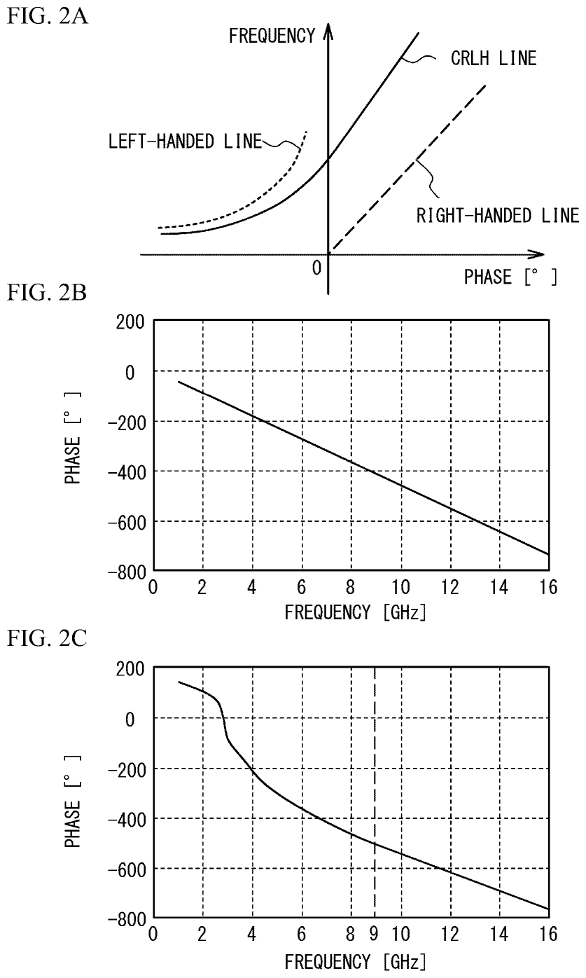

FIG. 2A is a diagram illustrating phase dispersion. A horizontal axis represents the phase of the signal at the time when the signal passes through the line. A vertical axis represents the frequency of the signal. In FIG. 2A, a dashed line represents phase dispersion of a right-handed line. A dotted line represents phase dispersion of a left-handed line. A solid line represents phase dispersion of composite right/left-handed transmission line 18. The phase dispersion of the right-handed line is linear. The phase dispersion of the left-handed line is nonlinear. The phase dispersion of composite right/left-handed transmission line 18 is a composite of the characteristics of the right-handed line and the characteristics of the left-handed line, and has a nonlinear portion and a linear portion.

In the right-handed transmission line, since the phase dispersion is linear, it is difficult to optimize the delay amount of the signal for each frequency. In order to change the slope of the phase dispersion, the transmission line may be lengthened. However, the circuit is increased in size.

FIGS. 2B and 2C are diagrams each illustrating a phase of a signal. FIG. 2B is an example of the right-handed line. FIG. 2C is an example of composite right/left-handed transmission line 18. A horizontal axis of each of FIGS. 2B and 2C represents the frequency of the signal. A vertical axis represents the phase of the signal after passing through the line. The phases of the signals at frequencies from 0 GHz to 16 GHz are illustrated.

In the example of FIG. 2B, the phase change is linear over the entire band of frequencies illustrated. It is difficult to optimize the phase of the signal for each frequency. In the example of FIG. 2C, frequencies above about 9 GHz are the linear portion, where the phase changes linearly. Frequencies below about 9 GHz are the nonlinear portion, where the change in phase is non-linear. By changing the capacitance, inductance, or the like in composite right/left-handed transmission line 18, the slope of the linear portion is adjusted and the curve of the nonlinear portion is adjusted. The phase can be optimized in the frequency band.

According to the first embodiment, composite right/left-handed transmission line 18 is provided in line 14 connecting divider 10 and amplifier 13. As illustrated in FIG. 2A, the phase dispersion of composite right/left-handed transmission line 18 includes the nonlinear portion, thereby allowing for high design flexibility of phase design. By setting the capacitance, inductance, or the like of composite right/left-handed transmission line 18 to appropriate values, desired phase characteristics can be obtained in the wide operating band. By adjusting the phases of the signals by composite right/left-handed transmission line 18, the phases of the signals at the time of combining can be made close to the optimum over the wide operating band. In addition, the line length of composite right/left-handed transmission line 18 does not need to be increased in order to optimize the phases. Thus, amplifying circuit 100 is reduced in size. Amplifying circuit 100 can be reduced in size and can widen the operating band.

The operating band of amplifying circuit 100 is, for example, 0.5 GHz or more, 1 GHz or more, 1.5 GHz or more, or 2 GHz or more. In these bands, the phases of the signals to be combined may be brought close to the optimum values.

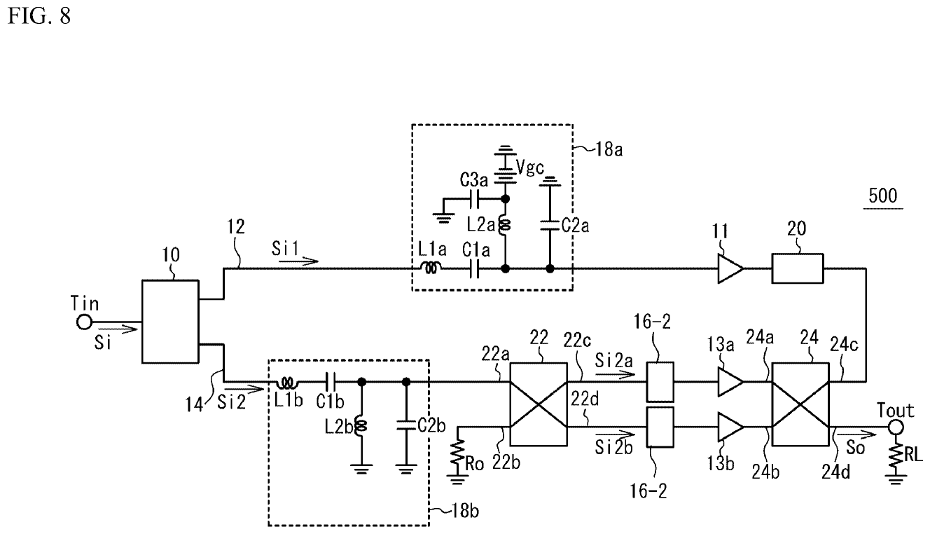

Composite right/left-handed transmission line 18 may be provided in at least one of line 12 or line 14. As in the example of FIG. 1A, composite right/left-handed transmission line 18 may be provided in line 14. Composite right/left-handed transmission line 18 may be provided in line 12. As in the example of FIG. 8 described later, composite right/left-handed transmission line 18 may be provided in both of line 12 and line 14.

Parasitic components are also considered in the design of composite right/left-handed transmission line 18. For example, a left-handed line having capacitor C1 and inductor L2 is designed, and composite right/left-handed transmission line 18 is designed with the parasitic components generated in the left-handed line as inductor L1 and capacitor C2.

Composite right/left-handed transmission line 18 includes capacitor C1, capacitor C2, inductor L1, and inductor L2. Capacitor C1 is connected in series to line 14 between divider 10 and amplifier 13, and blocks a DC signal. A capacitor for DC blocking does not need to be provided separately in line 14. Amplifying circuit 100 can be reduced in size.

Bias power supply Vgb is connected to inductor L2 of composite right/left-handed transmission line 18. A bias voltage is supplied from bias power supply Vgb to amplifier 13. Since a bias circuit does not need to be provided separately in line 14, amplifying circuit 100 can be reduced in size. The order of connection in composite right/left-handed transmission line 18 may be changed so that capacitor C1 is located near divider 10, and inductor L1 is located near amplifier 13.

### Second Embodiment

### (LMBA)

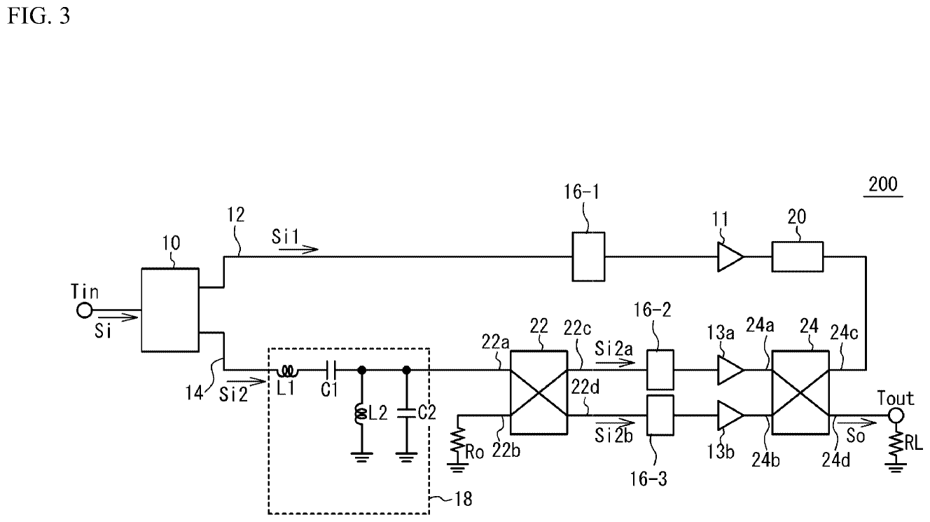

FIG. 3 is a circuit diagram illustrating an amplifying circuit 200 according to a second embodiment. Amplifying circuit 200 is a load modulated balanced amplifier (LMBA). The description of the same configuration as that of the first embodiment will be omitted. Amplifying circuit 200 is used in, for example, a base station of mobile communication.

Amplifying circuit 200 includes divider 10 (first divider), amplifier 11 (first amplifier), a matching circuit 20, composite right/left-handed transmission line 18, a divider 22 (second divider), an amplifier 13a (third amplifier), an amplifier 13b (fourth amplifier), and a load modulation circuit 24 (combiner). Amplifier 11, amplifier 13a, and amplifier 13b are connected in parallel between input terminal Tin and output terminal Tout.

Amplifier 11 is a control amplifier. Amplifier 11 is connected to one of output ends of divider 10. A line between divider 10 and amplifier 11 is referred to as line 12 (first line). A bias circuit 16-1 is provided in line 12. Bias circuit 16-1 supplies a bias voltage to amplifier 11.

Amplifier 13a and amplifier 13b are balanced amplifiers. A line from divider 10 to amplifier 13a and amplifier 13b is referred to as line 14 (second line). Composite right/left-handed transmission line 18 and divider 22 are provided in line 14.

Divider 22 is, for example, a hybrid coupler, and has an end 22a, an end 22b, an end 22c, and an end 22d. End 22a and end 22d are terminals diagonal to each other. End 22b and end 22c are terminals diagonal to each other. The output end of divider 10 is connected to end 22a of divider 22. Composite right/left-handed transmission line 18 is connected between divider 10 and end 22a of divider 22. Composite right/left-handed transmission line 18 in the second embodiment includes capacitor C1, capacitor C2, inductor L1, and inductor L2, and does not include a bias power supply and capacitor C3. End 22b of divider 22 is terminated by a reference load Ro. Amplifier 13a is connected to end 22c. Amplifier 13b is connected to end 22d.

A bias circuit 16-2 is connected between end 22c of divider 22 and amplifier 13a. A bias circuit 16-3 is connected between end 22d and amplifier 13b. Bias circuit 16-2 supplies a bias voltage to amplifier 13a. Bias circuit 16-3 supplies a bias voltage to amplifier 13b. In FIG. 3, bias circuit 16-1, bias circuit 16-2, and bias circuit 16-3 are illustrated as blocks. Each of these bias circuits has the same configuration as bias circuit 16 of FIG. 1.

Load modulation circuit 24 is, for example, a hybrid coupler, and has an end 24a (first end), an end 24b (second end), an end 24c (third end), and an end 24d (fourth end). End 24a and end 24d are terminals diagonal to each other. End 24b and end 24c are terminals diagonal to each other. Amplifier 13a is connected to end 24a. Amplifier 13b is connected to end 24b.

Amplifier 11 is connected to end 24c. Matching circuit 20 is provided between amplifier 11 and end 24c. Matching circuit 20 matches an impedance of matching circuit 20 as viewed from amplifier 11 with an impedance of load modulation circuit 24 as viewed from matching circuit 20. Output terminal Tout is connected to end 24d. Output terminal Tout is grounded via a load resistor RL. Load resistor RL is, for example, 50Ω.

Signal Si is input from input terminal Tin. Divider 10 divides signal Si into signal Si1 (first signal) and signal Si2 (second signal). Signal Si1 propagates through line 12 and is amplified by amplifier 11. The amplified signal Si1 passes through matching circuit 20 and is output to end 24c of load modulation circuit 24.

Signal Si2 passes through composite right/left-handed transmission line 18 and is output to end 22a of divider 22. Divider 22 divides signal Si2 into a signal Si2a (third signal) and a signal Si2b (fourth signal). A phase of signal Si2b is delayed by 90 degrees from a phase of signal Si2a.

Signal Si2a is output from end 22c and amplified by amplifier 13a. The amplified signal Si2a is output to end 24a of load modulation circuit 24. Signal Si2b is output from end 22d and amplified by amplifier 13b. The amplified signal Si2b is output to end 24b of load modulation circuit 24. Output signal So is output from end 24d of load modulation circuit 24 to output terminal Tout.

Amplifier 11 operates in class AB or class B. Amplifier 13a and amplifier 13b operate in class C. When the power of input signal Si is small, amplifier 11 mainly amplifies input signal Si. When the power of input signal Si is large, amplifier 11, amplifier 13a, and amplifier 13b amplify the peak of input signal Si. Thus, amplifier 11, amplifier 13a, and amplifier 13b amplify input signal Si.

When the power of input signal Si is small and amplifier 13a and amplifier 13b are not operating, signal Si1 input from end 24c to load modulation circuit 24 is divided into two signals Si1a and distributed to end 24a and end 24b. The phase of signal Si1a propagating from end 24c to end 24b is delayed by 90 degrees from the phase of signal Si1a propagating to end 24a. Signals Si1a are reflected at end 24a and end 24b. The phase of signal Si1a reflected at end 24a is delayed by 90 degrees from the phase of signal Si1a reflected at end 24b. The phases of two signals Si1a are matched at end 24d. Two signals Si1a are combined in end 24d. The combined signal is output to output terminal Tout as output signal So. A reflection coefficient of load modulation circuit 24 as viewed from amplifier 13a and amplifier 13b is more than 1, and load impedances of amplifier 13a and amplifier 13b are substantially high.

When the power of input signal Si is large and amplifier 13a and amplifier 13b operate, the phase of signal Si2b amplified by amplifier 13b is delayed by 90 degrees from the phase of signal Si2a amplified by amplifier 13a. Composite right/left-handed transmission line 18 adjusts the phase of signal Si2. At end 24a of load modulation circuit 24, the phases of signal Si1a and signal Si2a match. At end 24b, the phases of signal Si1a and signal Si2b match. A signal “Si1a+Si2a” combined in end 24a and a signal “Si1a+Si2b” combined in end 24b are combined in end 24d. The signals combined in end 24d is output as output signal So.

At this time, the reflection coefficient of load modulation circuit 24 as viewed from amplifier 13a and amplifier 13b is smaller than 1, and becomes smaller as the amplitudes of signal Si2a and signal Si2b become larger. Thus, the load impedances of amplifier 13a and amplifier 13b are substantially low. Load modulation circuit 24 modulates the load impedances of load modulation circuit 24 as viewed from each of amplifier 13a and amplifier 13b, depending on the amplitudes of each of signals Si2a and Si2b.

As an alternative to the above example of operation, amplifier 13a and amplifier 13b may operate in class AB or class B. Amplifier 11 may operate in class C. When the power of input signal Si is small, amplifier 13a and amplifier 13b mainly amplify input signal Si. When the power of input signal Si is large, amplifier 11, amplifier 13a, and amplifier 13b amplify the peak of input signal Si. Thus, amplifier 11, amplifier 13a, and amplifier 13b amplify input signal Si.

A harmonic processing circuit may be provided between amplifier 11 and matching circuit 20, between amplifier 13a and load modulation circuit 24, and between amplifier 13b and load modulation circuit 24. The harmonic processing circuit decreases harmonic components such as a second harmonic component of the signal.

According to the second embodiment, amplifying circuit 200 is an LMBA and operates in the wide operating band. The amount of phase delay of high frequency signal varies depending on frequency. In order to widen the operating band, the phase of the signal may be optimized for each frequency. As illustrated in FIG. 3, amplifying circuit 200 includes composite right/left-handed transmission line 18. As illustrated in FIG. 2A, the phase dispersion of composite right/left-handed transmission line 18 includes the nonlinear portion, thereby allowing for high design flexibility of phase design. The phase can be optimized in the wide operating band by using composite right/left-handed transmission line 18. The line length of composite right/left-handed transmission line 18 does not need to be increased. Amplifying circuit 200 can be reduced in size and can widen the operating band.

Amplifying circuit 200 is an LMBA, and is used in, for example, a base station of mobile communication. The LMBA can have a wider operating band compared to a Doherty amplifying circuit. According to the second embodiment, in the LMBA, the operating band can be made broader by adjusting the phase in the wide operating band.

In the example of FIG. 3, composite right/left-handed transmission line 18 is provided in line 14 between divider 10 and divider 22. The phase of signal Si2 is adjusted by composite right/left-handed transmission line 18. Signal Si2 after the phase adjustment is divided by divider 22. The divided signal Si2a and signal Si2b are combined. The phases of signals at the time of combining can be brought close to optimum in the wide operating band. In the wide operating band, characteristics of amplifying circuit 200, such as drain efficiency, are improved.

As illustrated in FIG. 3, composite right/left-handed transmission line 18 is provided in front of amplifier 13a and amplifier 13b. The signal before amplification propagates through composite right/left-handed transmission line 18, and the phase is adjusted. The signal after the phase adjustment is amplified. The signal after amplification is not lost by composite right/left-handed transmission line 18.

Amplifying circuit 200 includes load modulation circuit 24. Signal Si2a is input to end 24a of load modulation circuit 24. Signal Si2b is input to end 24b. Signal Si1 is input to end 24c. Load modulation circuit 24 combines the signals and outputs output signal So. Composite right/left-handed transmission line 18 brings the phases of the signals at the time of combining closer to the optimum in the wide operating band. Amplifying circuit 200 can widen the operating band.

Composite right/left-handed transmission line 18 includes capacitor C1, capacitor C2, inductor L1, and inductor L2. Capacitor C1 is connected in series to line 14 between divider 10 and divider 22, and blocks a DC signal. A capacitor for DC blocking does not need to be provided separately in line 14. Amplifying circuit 200 can be reduced in size.

### Third Embodiment

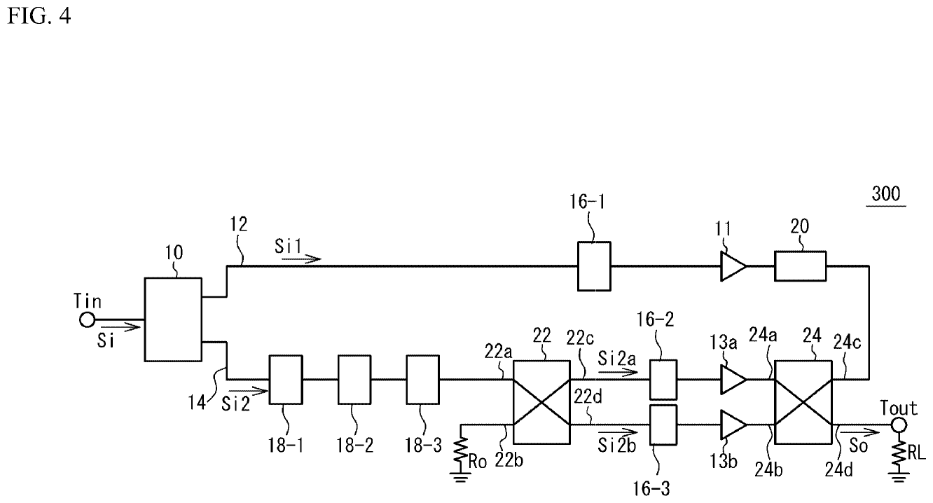

FIG. 4 is a circuit diagram illustrating an amplifying circuit 300 according to a third embodiment. Amplifying circuit 300 includes three composite right/left-handed transmission lines. In FIG. 4, a composite right/left-handed transmission line of one cell is illustrated as one block. The description of the same configuration as that of the first embodiment or the second embodiment will be omitted.

As illustrated in FIG. 4, a composite right/left-handed transmission line 18-1, a composite right/left-handed transmission line 18-2, and a composite right/left-handed transmission line 18-3 are provided in line 14 in order from a position near divider 10. Each of the composite right/left-handed transmission lines includes series-connected inductor L1 and series-connected capacitor C1, and shunt-connected inductor L2 and shunt-connected capacitor C2, as in composite right/left-handed transmission line 18 of FIG. 3. Three composite right/left-handed transmission lines are designed so that the phases are optimized.

### Comparative Example

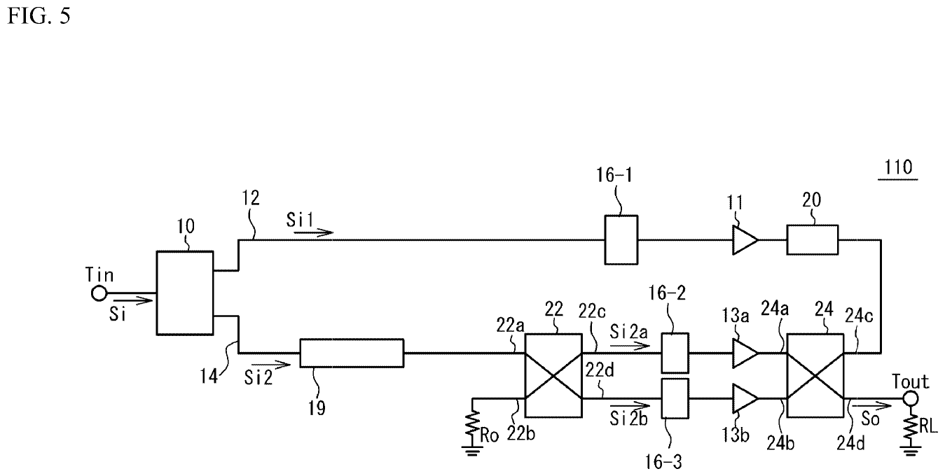

FIG. 5 is a circuit diagram illustrating an amplifying circuit 110 according to a comparative example. Amplifying circuit 110 does not include a composite right/left-handed transmission line, but includes a transmission line 19. Transmission line 19 is, for example, a microstrip line, and is provided in line 14.

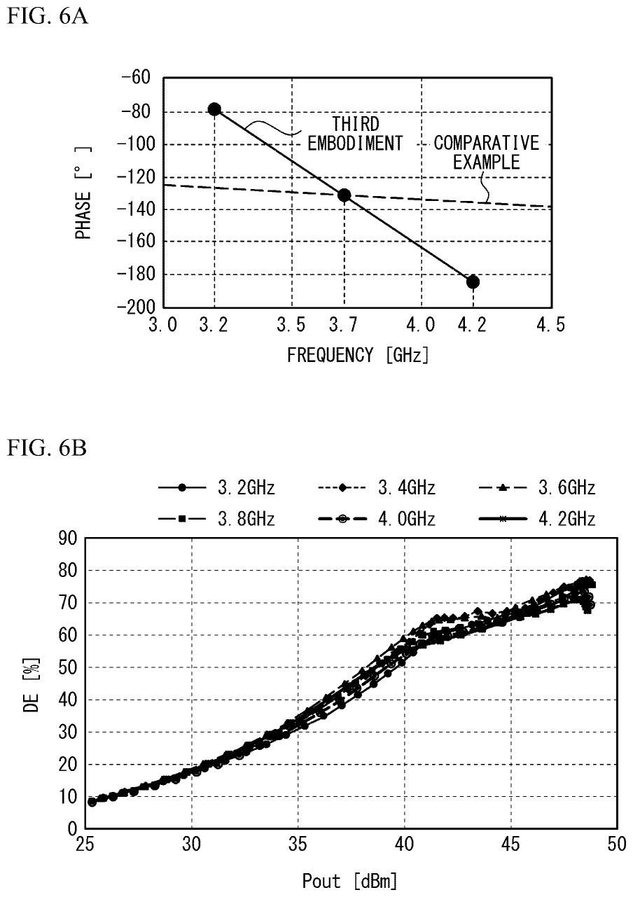

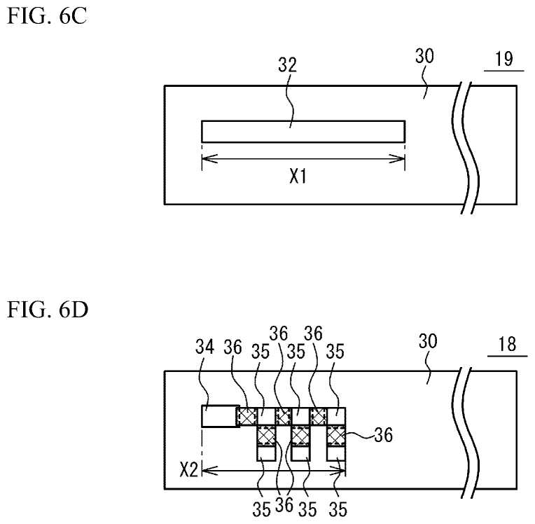

FIG. 6A is a diagram illustrating phases, and the phases of signals for each frequency are calculated in the comparative example and the third embodiment. The horizontal axis represents the frequency of the signal. The vertical axis represents the phase of the signal after passing through the line. The dashed line represents the comparative example. A phase delay amount in transmission line 19 of the comparative example is about 130 degrees. The solid line represents the third embodiment. In each of the composite right/left-handed transmission lines, L1 is equal to 0.7 nH, L2 is equal to 1.4 nH, C1 is equal to 0.56 pF, and C2 is equal to 0.28 pF. A characteristic impedance of each composite right/left-handed transmission line is 50Ω. The dots in FIG. 6A represent the optimal phases at signal frequencies of 3.2 GHZ, 3.7 GHZ and 4.2 GHz.

In the comparative example, the phase of the signal at a frequency of 3.7 GHz can be optimized. However, the phases deviates from the optimum values at frequencies below and above 3.7 GHZ. As the frequency moves away from 3.7 GHZ, the phase deviates more significantly from the optimum phase. By setting the phase delay amount of transmission line 19 to 490 degrees, the phase can be optimized over the band from 3.2 GHz to 4.2 GHz. However, transmission line 19 becomes long, and amplifying circuit 110is increased in size. As illustrated in FIG. 6A, in the third embodiment, the phases of the signals can be optimized over the band from 3.2 GHz to 4.2 GHz by using three composite right/left-handed transmission lines. The composite right/left-handed transmission line of three cells is shorter than transmission line 19 of 490 degrees. Thus, amplifying circuit 300 can be reduced in size.

FIG. 6B is a diagram illustrating drain efficiency. A horizontal axis represents a power Pout of the signal amplified by amplifier 13a and amplifier 13b. A vertical axis represents a drain efficiency DE of the amplifier. The frequencies of the signals range from 3.2 GHz to 4.2 GHz. Circles and a solid line represent an example at a frequency of 3.2 GHz. Diamonds and a dotted line represent an example at a frequency of 3.4 GHz. Triangles and a dashed line represent an example at a frequency of 3.6 GHz. Squares and a one-dot chain line represent an example at a frequency of 3.8 GHz. Double circles and a dashed line represent an example at a frequency of 4.0 GHz. Asterisks and a solid line represent an example at a frequency of 4.2 GHz.

At all frequencies, the drain efficiency increases with an increase in power. As illustrated in FIG. 6A, the phases of the signals are optimized in the range from 3.2 GHz to 4.2 GHz, and thus the drain efficiency is improved as illustrated in FIG. 6B. According to the third embodiment, both the improvement of the drain efficiency and reduction in size of amplifying circuit 300 can be achieved.

FIG. 6C is a plan view illustrating transmission line 19. A wiring pattern 32 is provided on a surface of a substrate 30. Substrate 30 includes, for example, a dielectric. A ground pattern (not illustrated) is provided at a position overlapping wiring pattern 32 on a back surface of substrate 30. Substrate 30, wiring pattern 32, and the ground pattern form transmission line 19 (microstrip line). A length of transmission line 19 is referred to as X1. When the phase delay amount is 130 degrees, the length X1 is 23 mm. However, it is difficult to adjust the phase. When the phase delay amount is 490 degrees, the length X1 is 71 mm. Transmission line 19 becomes long, and amplifying circuit 110 is increased in size.

FIG. 6D is a plan view illustrating one composite right/left-handed transmission line 18. A wiring pattern 34, a plurality of wiring patterns 35, and a plurality of chip components 36 are provided on substrate 30. In the example of FIG. 6D, chip components 36 are hatched. Wiring pattern 34 forms a microstrip line together with a ground pattern (not illustrated). The microstrip line corresponds to, for example, line 14 in FIG. 5. The plurality of wiring patterns 35 are spaced apart from each other and from wiring pattern 34. Chip components 36 are connected to the plurality of wiring patterns 35. Chip components 36 and parasitic components correspond to an inductor or a capacitor of composite right/left-handed transmission line 18. A length X2 of composite right/left-handed transmission line 18 is, for example, 13 mm. The sum of the lengths of the three composite right/left-handed transmission lines is about 39 mm.

According to the third embodiment, three composite right/left-handed transmission lines are provided in line 14 of amplifying circuit 300. As illustrated in FIG. 6A, the phase can be optimized in the wide operating band, for example, in about 1 GHz. For example, three composite right/left-handed transmission lines may be provided instead of transmission line 19 having a delay amount of 490 degrees. Amplifying circuit 300 can be reduced in size as compared with the example in which transmission line 19 is provided.

The number of composite right/left-handed transmission lines provided in line 14 may be two, three or more, four or more, or five or more. The phase can be adjusted in the wide operating band of 1 GHz or more.

### Fourth Embodiment

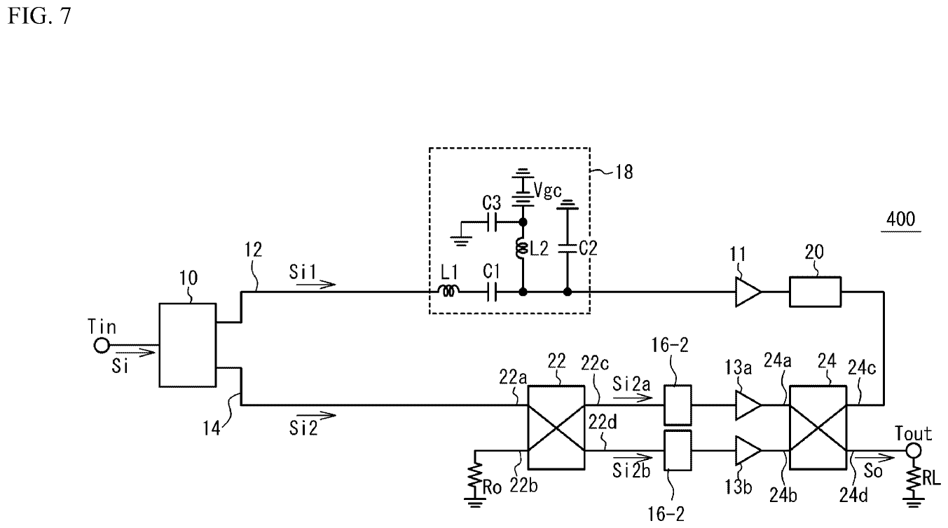

FIG. 7 is a circuit diagram illustrating an amplifying circuit 400 according to a fourth embodiment. Composite right/left-handed transmission line 18 is provided in line 12. A composite right/left-handed transmission line is not provided in line 14.

According to the fourth embodiment, since composite right/left-handed transmission line 18 is provided in line 12, the phase of signal Si1 is adjusted. The phase of signal at the time of combining can be brought close to optimum in the wide operating band. Amplifying circuit 400 can be reduced in size and can widen the operating band.

A plurality of composite right/left-handed transmission lines may be provided in line 12. For example, by providing three composite right/left-handed transmission lines in line 12, the phase can be brought close to the optimum value in the 1 GHz band as illustrated in FIG. 6A.

Capacitor C1 is provided in line 12. Capacitor C1 has a function of DC blocking. A capacitor for the DC blocking does not need to be provided separately in line 12. Amplifying circuit 400 can be reduced in size.

Bias power supply Vgc is connected to inductor L2 of composite right/left-handed transmission line 18. Bias power supply Vgc supplies a bias voltage to amplifier 11. Since another bias circuit does not need to be provided in line 12, amplifying circuit 400 can be reduced in size.

### Fifth Embodiment

FIG. 8 is a circuit diagram illustrating an amplifying circuit 500 according to a fifth embodiment. Amplifying circuit 500 includes a composite right/left-handed transmission line 18a (first composite right/left-handed transmission line) and a composite right/left-handed transmission line 18b (second composite right/left-handed transmission line). Composite right/left-handed transmission line 18a is provided in line 12.

Composite right/left-handed transmission line 18a includes a capacitor C1a, a capacitor C2a, a capacitor C3a, an inductor L1a, and an inductor L2a. Bias power supply Vgc is connected to inductor L2a. Composite right/left-handed transmission line 18b includes a capacitor C1b, a capacitor C2b, an inductor L1b, and an inductor L2b.

According to the fifth embodiment, since composite right/left-handed transmission line 18a is provided in line 12, the phase of signal Si1 is adjusted. Since composite right/left-handed transmission line 18b is provided in line 14, the phase of signal Si2 is adjusted. The phases of signals at the time of combining can be brought close to optimum in the wide operating band. Amplifying circuit 500 can be reduced in size and can widen the operating band.

As illustrated in the second embodiment to the fifth embodiment, the composite right/left-handed transmission line is provided in at least one of line 12 or line 14. In the example of FIG. 8, the composite right/left-handed transmission line is provided in both of line 12 and line 14. Thus, amplifying circuit 500 can be reduced in size as described below.

Capacitor C1a of composite right/left-handed transmission line 18a is connected in series to line 12 and has a function of DC blocking. Composite right/left-handed transmission line 18a includes bias power supply Vgc. A bias voltage is supplied to amplifier 11 from bias power supply Vgc of composite right/left-handed transmission line 18a. Apart from composite right/left-handed transmission 18a, a capacitor for the DC blocking and a bias circuit do not need to be provided in line 12. Capacitor C1b of composite right/left-handed transmission line 18b is connected in series to line 14 and has a function of DC blocking. Apart from capacitor C1b, a capacitor for the DC blocking does not need to be provided in line 14. Amplifying circuit 500 can be reduced in size.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

What is claimed is:

1. An amplifying circuit comprising:
a first divider that divides an input signal into a first signal and a second signal;
a first amplifier that amplifies the first signal;
a second amplifier that amplifies the second signal;
a combiner that combines the first signal and the second signal to output the combined signal as an output signal; and
at least one composite right/left-handed transmission line connected to at least one of a first line connecting the first divider to the first amplifier or a second line connecting the first divider to the second amplifier, the at least one composite right/left-handed transmission line adjusting a phase of at least one of the first signal flowing through the first line and the second signal flowing through the second line.

2. The amplifying circuit according to claim 1,
wherein the combiner is a load modulation circuit that modulates a load of the second amplifier, and
the amplifying circuit is a load modulated balanced amplifier.

3. The amplifying circuit according to claim 2, further comprising:
a second divider provided in the second line,
wherein the second divider divides the second signal into a third signal and a fourth signal,
the second amplifier includes a third amplifier and a fourth amplifier,
the third amplifier amplifies the third signal,
the fourth amplifier that amplifies the fourth signal, and
the at least one composite right/left-handed transmission line is connected to at least one of the first line and the second line between the first divider and the second divider.

4. The amplifying circuit according to claim 3,
wherein the combiner has a first end, a second end, a third end, and a fourth end,
the third signal amplified by the third amplifier is input to the first end,
the fourth signal amplified by the fourth amplifier is input to the second end,
the first signal amplified by the first amplifier is input to the third end, and
the output signal is output from the fourth end.

5. The amplifying circuit according to claim 3,
wherein the at least one composite right/left-handed transmission line includes a plurality of composite right/left-handed transmission lines, and
the plurality of composite right/left-handed transmission lines are connected to at least one of the first line and the second line between the first divider and the second divider.

6. The amplifying circuit according to claim 5,
wherein the at least one composite right/left-handed transmission lines includes three or more composite right/left-handed transmission lines.

7. The amplifying circuit according to claim 1,
wherein the at least one composite right/left-handed transmission line includes a first inductor, a first capacitor, a second inductor, and a second capacitor,
when the at least one composite right/left-handed transmission line is provided in the first line, the first inductor and the first capacitor are connected in series to the first line, and the second inductor and the second capacitor are shunt-connected between the first capacitor and the first amplifier, and
when the at least one composite right/left-handed transmission line is provided in the second line, the first inductor and the first capacitor are connected in series to the second line, and the second inductor and the second capacitor are shunt-connected between the first capacitor and the second amplifier.

8. The amplifying circuit according to claim 7,
wherein the second inductor is connected to a bias power supply,
the bias power supply supplies a bias voltage to the first amplifier when the at least one composite right/left-handed transmission line is provided in the first line, and
the bias power supply supplies a bias voltage to the second amplifier when the at least one composite right/left-handed transmission line is provided in the second line.

9. The amplifying circuit according to claim 1,
wherein the at least one composite right/left-handed transmission line includes a first composite right/left-handed transmission line and a second composite right/left-handed transmission line,
the first composite right/left-handed transmission line is provided in the first line, and
the second composite right/left-handed transmission line is provided in the second line.
